(19) United States
(12) Patent Application Publication
(10) Pub. No.: US 2021/0408077 A1
(43) Pub. Date: Dec. 30, 2021

(54) ARRAY SUBSTRATE, MANUFACTURING METHOD OF PHOTO-ETCHING COMPENSATION STRUCTURE THEREOF, AND DISPLAY PANEL

(71) Applicant: WUHAN CHINA STAR OPTOELECTRONICS TECHNOLOGY CO., LTD., Wuhan (CN)

(72) Inventor: Hanchen LIU, Wuhan (CN)

(73) Assignee: WUHAN CHINA STAR OPTOELECTRONICS TECHNOLOGY CO., LTD., Wuhan (CN)

(21) Appl. No.: 16/770,622

(22) PCT Filed: Mar. 18, 2020
(86) PCT No.: PCT/CN2020/079869

§ 371 Date: Jun. 8, 2020

(30) Foreign Application Priority Data
Feb. 19, 2020 (CN) 202010102202.2

(51) Int. Cl. H01L 27/12; H01L 29/786; G02F 1/1362

(52) U.S. Cl. CPC H01L 27/1244; G02F 1/136295; H01L 27/1288; H01L 29/78633

(57) ABSTRACT

The disclosure provides a photo-etching compensation structure of an array substrate, including a substrate, a base layer, a light-sensitive layer, and a photo-etching compensation pattern layer disposed between the substrate and the base layer. The photo-etching compensation pattern layer includes a plurality of compensation patterns distributed in an array arrangement, and the compensation patterns change a thickness of the base layer along a thickness direction of the substrate, thereby making a thickness of the light-sensitive layer in an area corresponding to the compensation patterns less than a thickness of the light-sensitive layer in a corresponding area around the compensation patterns.

### FIELD

The present disclosure relates to the field of display technologies, and more specifically, relates to a photo-etching compensation structure of an array substrate, a manufacturing method thereof, and a display panel and the array substrate which adopt the photo-etching compensation structure.

### BACKGROUND

Consumer requirements for resolution of display panels continuously increase following development of electronic products. To further improve resolution, correspondingly, a pixel per inch (PPI) value needs to be increased.

A conventional display panel is as shown in FIG. 1. A display panel 40 includes a display area 41 and a fan-out area 43. The display area 41 is disposed on a middle portion of the display panel 40, and a fan-out area 43 is disposed on a side end of the display panel 40.

Please simultaneously refer to FIG. 2 and FIG. 3. FIG. 2 is a schematic partial enlarged view showing the display area in FIG. 1, and FIG. 3 is a schematic partial enlarged view showing the fan-out area in FIG. 1. A plurality of thin film transistors (TFTs) 411, and a plurality of gate lines 413 and a plurality of data lines 415, which are disposed in a vertically crossing arrangement, are disposed in the display area 41. An end of the gate lines 413 and an end of the data lines 415 are connected to the display area 41, and another end of the gate lines 413 and another end of the data lines 415 extend to a driver chip 45 through the fan-out area 43.

Stages of gate driver on array (GOA) circuits continuously increase, which reduces widths of the GOA circuits, thereby causing TFTs of the GOA circuits to be considerably crowded, further reducing distances between the gate lines 413 and the TFTs 411 and distances between the data lines 415 and the TFTs 411, and also causing conductive wires introduced from the display area 41 to the fan-out area 43 to be considerably crowded.

In a manufacturing process of TFT-LCD arrays, because high-solution products are involved, boundary values of parameters of TFT-LCD arrays become increasingly smaller and demands for the TFT-LCD arrays become higher. In conventional technologies, conductive wires are formed on a substrate by an exposure process. However, limited by factors such as a bending tendency of wires affected by materials, temperature, and types of wires, as well as exposure precision and a period of developing process, a width of the conductive wires cannot be consistent, even leading to an occurrence of short-circuiting on adjacent conductive wires.

Industry also provides a corresponding compensation method to solve a problem that widths of the conductive wires in different areas cannot be consistent, as shown in FIG. 4 and FIG. 5. However, to realize the above method, different areas need to be processed by using masks with different sizes, which increases costs and reduces efficiency, as well as poses higher demands on manufacturing apparatuses and space.

As a result, to achieve different required densities of the conductive wires in different areas of conventional display panels as well as obtain higher processing accuracy, different areas of the conductive wires need to be processed by a consistent process with a single photomask.

In conventional display panels, distances between conductive wires in different areas are too short, leading to short-circuiting, thereby increasing processing costs and reducing efficiency.

### SUMMARY

The present disclosure provides a photo-etching compensation structure of an array substrate, including a substrate, a base layer, a light-sensitive layer, and a photo-etching compensation pattern layer. The base layer is disposed on a side surface of the substrate, the light-sensitive layer disposed on a side surface of the base layer away from the substrate, and the photo-etching compensation pattern layer is disposed between the substrate and the base layer. The photo-etching compensation pattern layer includes a plurality of compensation patterns distributed in an array arrangement, and the compensation pattern change a thickness of the base layer along a thickness direction of the substrate, thereby making a thickness of the light-sensitive layer in an area corresponding to the compensation patterns less than a thickness of the light-sensitive layer in a corresponding area around the compensation patterns.

The present disclosure provides a method of manufacturing an array substrate, including following steps: providing a substrate; providing a photo-etching compensation pattern layer formed on a side surface of the substrate, wherein the photo-etching compensation pattern layer includes a plurality of compensation patterns disposed in an array arrangement; providing a base layer formed on the side surface of the substrate, wherein the compensation patterns are disposed between the substrate and the base layer; providing a light-sensitive layer disposed on the base layer, wherein a thickness of the light-sensitive layer in an area corresponding to the compensation patterns is less than a thickness of the light-sensitive layer in a corresponding area around the compensation patterns along a thickness direction of the substrate; and providing a photomask, and performing photographic and developing processes on the light-sensitive layer to form a plurality of grooves, wherein the grooves correspond to the compensation patterns along the thickness direction of the substrate.

The present disclosure further provides an array substrate, including a substrate, a photo-etching compensation pattern layer, a base layer, and a wiring layer. The photo-etching compensation pattern layer is disposed on a side surface of the substrate and includes a plurality of compensation patterns. The base layer is formed on the side surface of the substrate. A pattern formed from the wiring layer includes a plurality of grooves or a plurality of minor holes, the grooves or the minor holes form a plurality of interval areas for spacing patterns, and the compensation patterns respectively correspond to the interval areas for spacing patterns along a thickness direction of the substrate.

The present disclosure further provides a display panel, including an array substrate and a color filter substrate, which are spaced apart from and disposed opposite to each other, and a liquid crystal layer disposed between the array substrate and the color filter substrate. The array substrate includes a plurality of grooves, a plurality of minor holes, and a photo-etching compensation pattern layer. The grooves and the minor holes form a plurality of interval areas for spacing patterns. The photo-etching compensation pattern layer includes a plurality of compensation patterns, and each compensation patterns corresponds to one of the compensation patterns along a thickness direction of the array substrate.

Regarding the beneficial effects: in the present disclosure, a plurality of photo-etching patterns are defined between an array substrate and a base layer to form a photo-etching compensation structure, thereby increasing a thickness of the base layer. During a process of manufacturing a light-sensitive layer, due to self-leveling effect, a thickness of a light-sensitive layer in an area corresponding to compensation patterns is less than a thickness of a light-sensitive layer in a corresponding area around the compensation patterns. There is a negative linear correlation between a thickness of the light-sensitive layer and an accuracy of a critical dimension of interval areas where the base layer covers. Therefore, by disposing the photo-etching patterns under the light-sensitive layer and reducing the thickness of the light-sensitive layer on the area where the base layer covers, widths of grooves are increased after a photosensitive process and a developing process. As a result, distances between adjacent conductive wires are increased, and a processing difficulty and requirements for manufacturing apparatuses are reduced. Furthermore, for same types of display panels, there is no need to change a size of a photomask according to densities of different conductive wires, thereby reducing costs and improving efficiency.

Moreover, because the compensation patterns may be directly formed by a conventional process of manufacturing conductive wires, accuracy and yield rate of products can be improved without any additional increased cost. Of course, the compensation patterns may also be directly formed by an individual exposure process based on a manufacturing process of conventional TFT arrays, thereby simplifying processes.

### DESCRIPTION OF DRAWINGS

FIG. 1 is a schematic plan view showing a structure of a conventional display panel.

FIG. 2 is a schematic partial enlarged view showing an area A in FIG. 1.

FIG. 3 is a schematic partial enlarged view showing an area B in FIG. 1.

FIG. 4 is a schematic view showing a result showing that a display area and a fan-out area are processed by a consistent process in conventional technologies.

FIG. 5 is a schematic view showing a result showing that a display area and a fan-out area are processed by conventional technologies combined with a compensation process for widths of conductive wires in the display area.

FIG. 6 is a schematic stereoscopic view showing a structure of a display panel according to the present disclosure.

FIG. 7 is a schematic plan view showing an array substrate in FIG. 6.

FIG. 8 is a schematic enlarged view showing an area C of the array substrate in a display area in FIG. 7.

FIG. 9 is a schematic enlarged view showing an area D of the array substrate in a surrounding area in FIG. 7.

FIG. 10 is a partial sectional view showing the surrounding area in FIG. 7.

FIG. 11 is a schematic view showing manufacturing steps of a second interval in the surrounding area in FIG. 10.

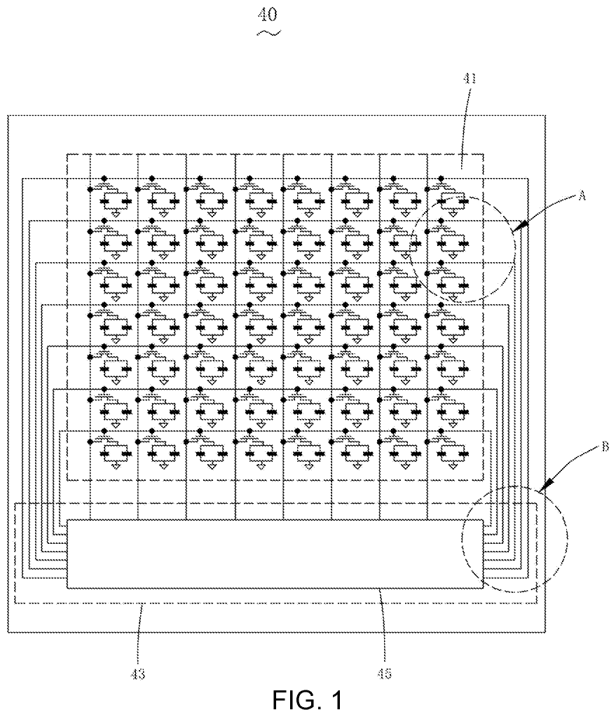

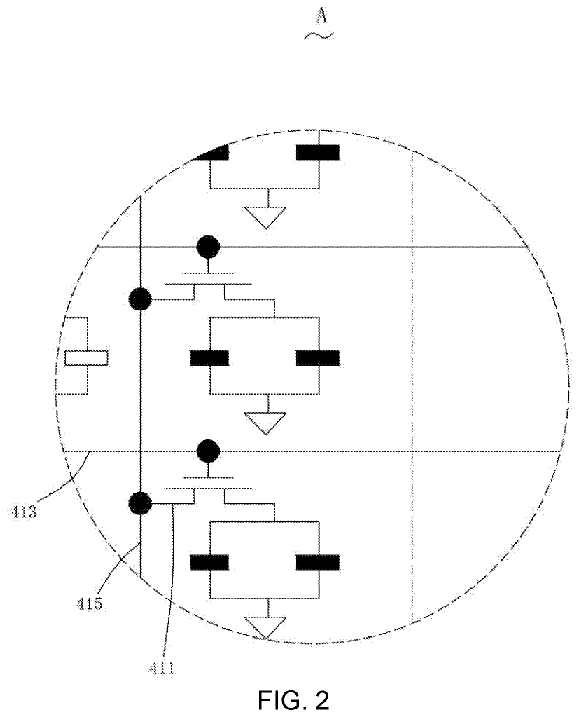

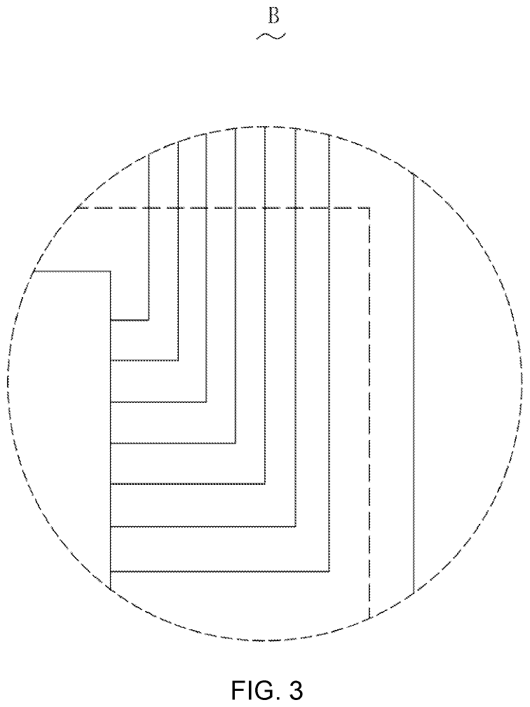

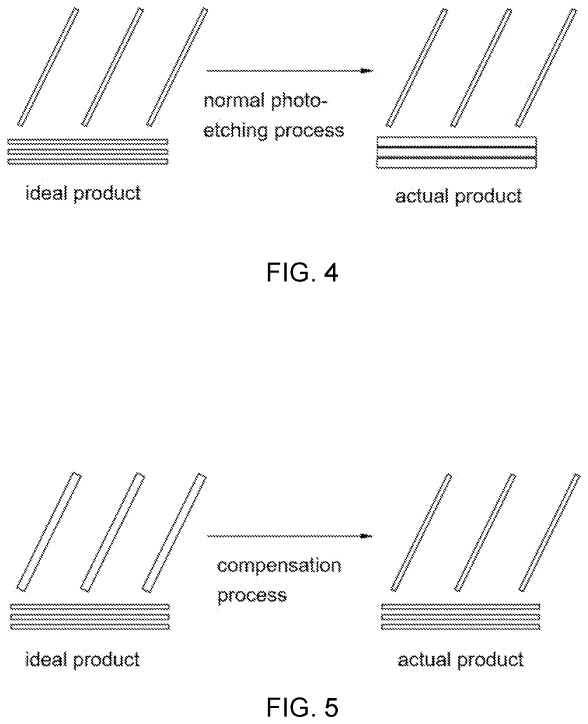

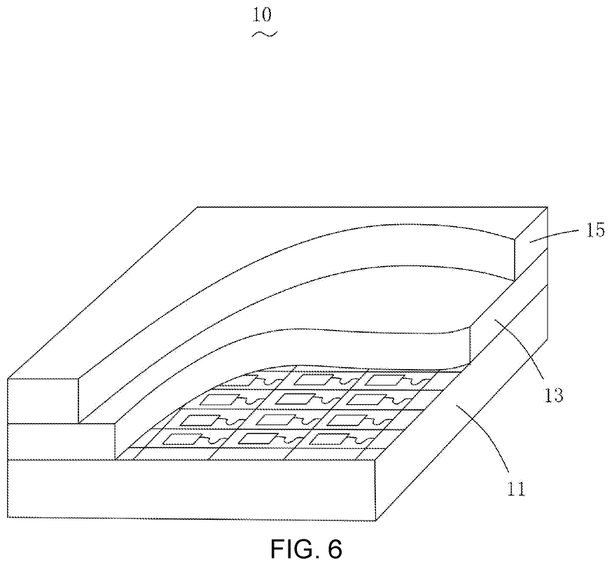

### DETAILED DESCRIPTION

Hereinafter preferred embodiments of the present disclosure will be described with reference to the accompanying drawings, which can fully describe the technical contents of the present disclosure to make the technical content of the present disclosure clearer and easy to understand. The following embodiments and features thereof can be combined as long as they do not contradict each other.

The following description of the various embodiments is provided with reference to the accompanying drawings. The embodiments described with reference to the attached drawings are all exemplary and are intended to illustrate and interpret the present disclosure. It should be understood that terms such as “top”, “bottom”, “upper”, “lower”, “front”, “rear”, “left”, “right”, “inside”, “outside”, “lateral”, “around”, “central”, “horizontal”, “vertical”, “longitudinal”, “axial”, “radial”, “uppermost”, “lowermost”, as well as derivatives thereof should be construed to refer to the orientation as then described or as shown in the drawings under discussion. These relative terms are for convenience of description, and shall not be construed as causing limitations to the present disclosure. In addition, the identical or similar reference numerals constantly denote the identical or similar elements or elements having the identical or similar functions.

Please refer to FIG. 6, a schematic stereoscopic view showing a structure of a display panel is provided. The display panel 10 includes an array substrate 11, a liquid crystal layer 13, and a color filter substrate 15. The array substrate 11 and the color filter substrate 15 are spaced apart from and disposed opposite to each other, and the liquid crystal layer 13 is disposed between the array substrate 11 and the color filter substrate 15.

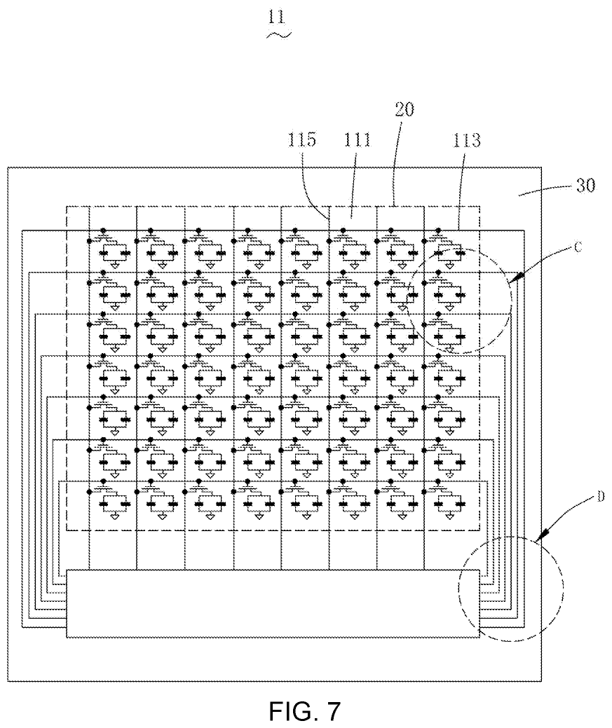

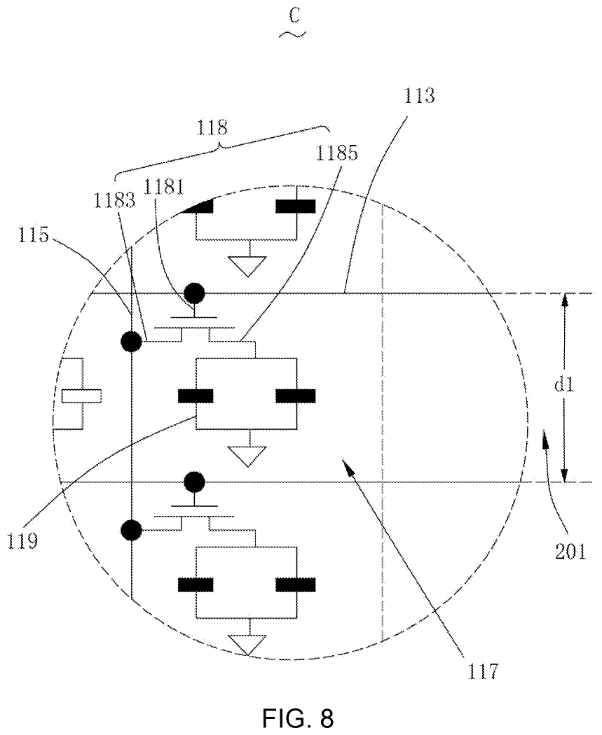

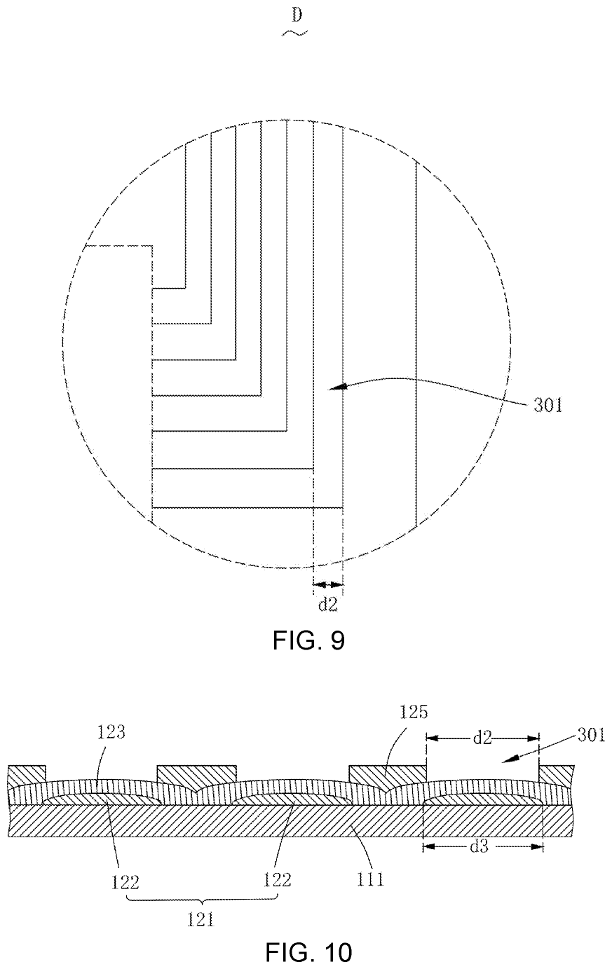

Please refer to FIGS. 7 to 9. FIG. 7 is a schematic plan view showing an array substrate in FIG. 6, FIG. 8 is a schematic enlarged view showing an area C of the array substrate in a display area in FIG. 7, and FIG. 9 is a schematic enlarged view showing an area D of the array substrate in a surrounding area in FIG. 7. The array substrate 11 and the color filter substrate 15 are stacked on a display area 20 in a middle area and a surrounding area 30 surrounding the display area 20. The display area 20 is defined in the middle area and is configured to display an image. The surrounding area 30 is defined around the display area 20, and a plurality of driving devices and a plurality of conductive wires are disposed in the surrounding area 30 to realize a wiring layout.

In the display area 20, the array substrate 11 includes a substrate 111, and a plurality of gate lines 113 and a plurality of data lines 115 are disposed on a surface of the substrate 111 in a vertically cross-arrangement. The gate lines 113 and the data lines 115 define a plurality of pixel areas 117 disposed in an array arrangement. A thin film transistor (TFT) 118 and a pixel electrode 119 are disposed in each of the pixel areas 117. A gate 1181 of the TFT 118 is correspondingly electrically connected to one of the gate lines 113, a source 1183 is correspondingly electrically connected to one of the data lines 115, and a gate 1185 is correspondingly electrically connected to the pixel electrode 119. In the display area 20, the gate lines 113, the data lines 115, and conductive wires in the pixel areas 117 define a plurality of first conductive wires, and a plurality of first intervals 201 is defined between adjacent first conductive wires.

The gate lines 113 and the data lines 115 extend from the display area 20 to the surrounding area 30.

Functional areas such as a plurality of common electrode terminals (not shown), an array row driving circuit (not shown), an electrostatic discharge terminal (not shown), a fan-out area, an electrode connected to a driver chip, an electrode welded on a printed circuit board, and a reuse driving architecture are disposed in the surrounding area 30. Different functional areas are electrically connected to each other by conductive wires. In the surrounding area 30, the conductive wires are second conductive wires, and a plurality of second intervals are defined between adjacent second conductive wires.

Widths d1 of the first intervals 201 between adjacent first conductive wires in the display area 20 are greater than widths d2 of the second intervals 301 between adjacent second conductive wires in the surrounding area 30.

Please refer to FIG. 10, a partial sectional view showing the surrounding area in FIG. 7 is provided. In the surrounding area 30, the array substrate 11 includes a substrate 111, and a compensation pattern layer 121, a base layer 123, and a second conductive wiring layer 125, which are sequentially formed on a side surface of the substrate 111.

The substrate 111 is a glass substrate, which supports the first conductive wires and the second conductive wires to form the display area 20 and the surrounding area 30.

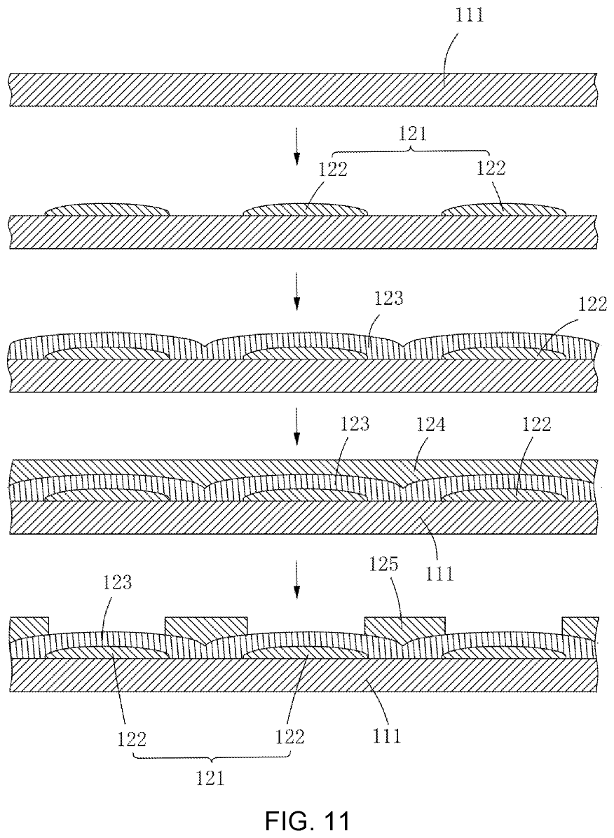

The compensation pattern layer 121 includes a plurality of compensation patterns 122 distributed on a surface of the substrate 111 in an array arrangement. The compensation patterns 122 are disposed between the substrate 111 and the base layer 123. The compensation patterns 122 correspond to the second intervals 301 along a thickness direction of the substrate. Widths d3 of the compensation patterns 122 are greater than the widths d2 of the second intervals 301 along an extending direction of the compensation patterns. Of course, to improve the above embodiment, the widths d3 of the compensation patterns 122 may be equal to the widths d2 of the second intervals 301. The photo-etching compensation pattern layer 121 may be an amorphous silicon semiconductor layer, an insulating layer, or a metal conductive layer. Preferably, the compensation patterns 122 are formed between the substrate 111 and the base layer 123 by a photo-etching process. In the present embodiment, the compensation patterns 122 may be formed by performing one individual exposure process based on an exposure process of the TFT 118. Of course, the compensation patterns 122 may be formed not only by the above processing process, but also may be formed by other processing processes, a chemical deposition method, for example. Any method of adjusting a thickness of a light-sensitive layer (as shown in FIG. 11) configured to process conductive wires by forming a compensation layer between the base layer 123 and the substrate 111 is within the spirit and the protective scope of the present disclosure.

The base layer 123 is directly formed on a surface (an insulating layer or a semiconductor layer) of the substrate 111 and covers the surface of the substrate 111 and the compensation patterns 122. Preferably, the base layer 123 includes structures of an array substrate such as a light-shading layer, a gate layer, a gate insulating layer, and an active layer.

The second conductive wires 125 are conductive layers formed on the surface of the substrate 111 and may be wires in the fan-out area, a gate driving electrode terminal, a connecting driver chip, or an electrode terminal of a control circuit board. In a specific embodiment of the present disclosure, for those skilled in the art, any conductive wire on the array substrate 11 may be regarded as the second conductive wire as long as distances between adjacent conductive wires are within a predetermined range.

In the present embodiment, the display panel 10 includes the display area 20 in the middle area and the surrounding area 30 around the middle area. A plurality of first intervals are defined between adjacent conductive wires in the display area 20, a plurality of second intervals are defined between adjacent conductive wires in the surrounding area 30, and the first intervals are longer than the second intervals. That is, the distances between the conductive wires in the display area 20 and the distances between the conductive wires in the surrounding area 30 are different, and the first intervals are longer than the second intervals. Therefore, an arrangement of the conductive wires in the surrounding area 30 is denser than that of the conductive wires in the display area 20. Specifically, the intervals are a plurality of grooves or a plurality of minor holes formed on a surface of the array substrate 11. The grooves or the minor holes, which are the intervals between the conductive wires, are formed by performing an exposure process and a chemical deposition process on a surface of the base layer 123. Specifically, the first intervals 201 between the first conductive wires and the second intervals 301 between the second conductive wires may be the grooves or the minor holes.

An arrangement of the conductive wires in the display area 20 is relatively loose, and the first intervals between the first conductive wires are not covered by conductive wires. Correspondingly, the compensation patterns are not disposed in the display area 20, and processing accuracy of the first conductive wires is decided by a photomask with a predetermined size.

An arrangement of the conductive wires in the surrounding area 30 is relatively dense, and the second intervals between the second conductive wires are not covered by conductive wires. Correspondingly, the compensation patterns 122 are disposed in the surrounding area 30 by using the photomask used in the display area 20. The compensation patterns 122 may further compensate critical dimension deviations of edges of the second conductive wires, thereby lengthening the second intervals and ensuring processing accuracy of adjacent second conductive wires.

By disposing the compensation patterns 122 in an area having relatively dense arrangement of conductive wires, critical dimension deviations of intervals between adjacent conductive wires may be effectively compensated. Therefore, the intervals may be lengthened, an aperture ratio may be increased, and processing accuracy may be improved. Furthermore, a photomask does not need to be changed, so that costs may be reduced.

Compared with conventional technologies, in the array substrate 11 of the display panel provided by the present disclosure, a thickness of the base layer 123 is changed by the compensation patterns 122 disposed along the thickness direction of the substrate 11. Therefore, a thickness of the light-sensitive layer is reduced, distances between adjacent conductive wires are increased, and processing accuracy is improved. As a result, the processing accuracy of the conductive wires of the entire array substrate can be more ideal and more consistent.

Please refer to FIG. 11, a schematic view showing manufacturing steps of a second interval in the surrounding area is provided. The second conductive wires in the surrounding area 30 may be processed by following steps:

Step 01: providing the substrate 111;

Step 02: forming the compensation pattern layer 121 on the substrate 111, wherein the compensation pattern layer 121 includes the plurality of compensation patterns 122 distributed on a surface of the substrate 111.

In the step 02, the compensation patterns 122 are formed on interval areas, in which the grooves are to be disposed, along the thickness direction of the substrate 111. The photo-etching compensation pattern layer 121 may be an amorphous silicon semiconductor layer, an insulating layer, or a metal conductive layer, and is formed according to conventional technologies. For example, the photo-etching compensation pattern layer 121 may be formed by an exposure process or a chemical vapor deposition process. Specifically, the photo-etching compensation pattern layer 121 is formed by an individual exposure process.

Step 03: providing the base layer 123, wherein the base layer 123 is formed on a side surface of the substrate 111 and covers the substrate 111 and the compensation pattern layer 121.

In the step 03, the base layer 123 includes structures of an array substrate such as a light-shading layer, a gate layer, an insulating layer, an active layer, and an array substrate. The above layers may be formed by conventional technologies. For example, the light-shading layer may be formed by a coating process, the gate layer and the active layer may be formed by an exposure process and an etching process, and the gate insulating layer may be formed by a chemical vapor deposition process.

Step 04: providing a light-sensitive layer 124 disposed on the base layer 123, wherein a thickness of a light-sensitive layer 124 in an area correspondingly to the compensation patterns 122 is less than a thickness of a light-sensitive layer 124 in a corresponding area around the compensation patterns 122 along the thickness direction of the substrate 111.

In the step 04, the light-sensitive layer 124 may be formed by coating UV glue on a surface of the base layer 123. Because the photo-etching compensation pattern layer 121 is formed on the side surface of the substrate 111, a thickness of the base layer 123 is increased. Therefore, in a manufacturing process of the light-sensitive layer 124, due to self-leveling effect, the thickness of the light-sensitive layer in the area corresponding to compensation patterns 122 is less than the thickness of the light-sensitive layer in the area corresponding to the surround of the compensation patterns 122.

Step 05: providing a photomask (not shown), and performing a developing process on the light-sensitive layer by the photomask to form a plurality of second grooves or a plurality of minor holes, wherein the second grooves or the minor holes form a plurality of interval areas, and the compensation patterns respectively correspond to the interval areas along the thickness direction of the substrate 111. The second grooves corresponding to the second intervals between adjacent second conductive wires, and the second grooves are correspondingly disposed with respect to the compensation patterns 122 along the thickness direction of the substrate. Specifically, widths of the compensation patterns 122 are slightly greater than or equal to widths of the second grooves, as shown in FIG. 10.

Step 06: forming the second conductive wires spaced apart from each other on two sides of the second grooves, and removing the light-sensitive layer. Finally, the array substrate 11 is formed.

The second conductive wires may be formed by a conventional photo-etching process. A conductive layer is coated on a surface of the base layer 123 before the second conductive wires are formed, and the second conductive wires are formed by a photo-etching process. That is, a plurality of grooves or a plurality of minor holes are directly formed on a layer to be manufactured in an array arrangement before the second conductive wires are formed. The compensation patterns 122 are defined on areas corresponding to the grooves or the minor holes along the thickness direction of the substrate 111. A position where the compensation patterns 122 corresponding to is the layer to be manufactured, and the conductive layer where the compensation patterns 122 of the grooves or the minor holes are formed is a wiring layer.

It should be noted that the surrounding area is processed by a photo-etching process with a photomask, the display area is also processed by a photo-etching process with a photomask, and the above two photo-etching processes are basically same. The only difference therebetween is that the compensation pattern layer 121 needs to be formed in the surrounding area 30 to compensate widths of the second grooves, thereby lengthening intervals between the second conductive wires, making the intervals between the conductive wires in the display area 20 and the surrounding area 30 more accurate, and improving reliability of products.

In the array substrate 11 provided by the present disclosure, the first intervals and the second intervals do not need to be disposed in the surrounding area and the display area. Those skilled in the art can understand the array substrate includes at least two areas that have different densities of conductive wires. In the area having relatively dense conductive wires, low accuracy of intervals between the conductive wires due to a developing process needs to be compensated to lengthen the intervals between the conductive wires, thereby improving processing accuracy, increasing an aperture ratio, reducing processing costs, and enhancing processing efficiency. The display area and the surrounding area denote different areas that have different densities of conductive wires, but not specific areas.

Although the present disclosure has been described with preferred embodiments thereof, it is understood that many changes and modifications to the described embodiments can be carried out by reading and understanding the present disclosure and drawings thereof. The present disclosure includes such the changes and the modifications that are limited only by the appended claims. Regarding functions performed by the above components, terms used to describe such components are intended to correspond to any equivalent that performs the specified function of the components unless otherwise indicated, even if a structure of the equivalent is not identical to the disclosed structure of the present disclosure.

The above description is only an embodiment which does not limit the patent scope of the present disclosure. Equivalent structure or equivalent process transformations based on the description of the present disclosure and the contents of the drawings, for example, the combination of technical features between the embodiments, or directly or indirectly applied in other related technical fields, are included within the scope of patent protection of the present disclosure.

Furthermore, although specific features of the specification have been disclosed with respect to only one of several embodiments, such features may be combined with one or more other features which is/are beneficial to realize the present disclosure. Furthermore, it should be noted that terms such as “comprising”, “including”, “having”, or derivatives thereof used in specific embodiments or claims have a meaning of “comprising”. Moreover, it should be noted that “a plurality of” relates to two or more than two.

What is claimed is:

1. A photo-etching compensation structure of an array substrate, comprising:
a substrate;
a base layer disposed on a side surface of the substrate; and
a light-sensitive layer disposed on a side surface of the base layer away from the substrate, wherein the light-sensitive layer comprises a photo-etching compensation pattern layer disposed between the substrate and the base layer, the photo-etching compensation pattern layer comprises a plurality of compensation patterns distributed in an array arrangement, and the compensation patterns change a thickness of the base layer along a thickness direction of the substrate, thereby making a thickness of the light-sensitive layer in an area corresponding to the compensation patterns less than a thickness of the light-sensitive layer in a corresponding area around the compensation patterns.

2. The photo-etching compensation structure of the array substrate of claim 1, wherein the compensation patterns are formed between the substrate and the base layer by a photo-etching process.

3. The photo-etching compensation structure of the array substrate of claim 1, wherein the photo-etching compensation pattern layer is an amorphous silicon semiconductor layer, an insulating layer, or a metal conductive layer.

4. The photo-etching compensation structure of the array substrate of claim 1, wherein the base layer comprises a plurality of structures of the array substrate comprising a shading layer, a gate layer, an insulating layer, and an active layer.

5. The photo-etching compensation structure of the array substrate of claim 1, wherein a layer to be manufactured is disposed on the side surface of the base layer away from the substrate, and the light-sensitive layer is configured to form a photo-etching pattern during a process of forming a pattern of the layer to be manufactured.

6. A method of manufacturing an array substrate, comprising following steps:
providing a substrate;
providing a photo-etching compensation pattern layer formed on a side surface of the substrate, wherein the photo-etching compensation pattern layer comprises a plurality of compensation patterns disposed in an array arrangement;
providing a base layer formed on the side surface of the substrate, wherein the compensation patterns are disposed between the substrate and the base layer;
providing a light-sensitive layer disposed on the base layer, wherein a thickness of the light-sensitive layer in an area corresponding to the compensation patterns is less than a thickness of the light-sensitive layer in a corresponding area around the compensation patterns along a thickness direction of the substrate; and
providing a photomask, and performing photographic and developing processes on the light-sensitive layer to form a plurality of grooves, wherein the grooves correspond to the compensation patterns along the thickness direction of the substrate.

7. The method of claim 6, wherein widths of the compensation patterns are greater than or equal to widths of the grooves along a horizontally extending direction of the compensation patterns.

8. The method of claim 6, wherein the compensation patterns are formed by using an individual photo-etching mask.

9. The method of claim 6, wherein the photo-etching compensation pattern layer is an amorphous silicon semiconductor layer, an insulating layer, or a metal conductive layer.

10. The method of claim 6, wherein the base layer comprises a plurality of structures of the array substrate comprising a shading layer, a gate layer, an insulating layer, and an active layer.

11. The method of claim 6, wherein a layer to be manufactured is disposed on the side surface of the base layer away from the substrate, and the light-sensitive layer is configured to form a photo-etching pattern during a process of forming a pattern of the layer to be manufactured.

12. An array substrate, comprising:
a substrate;
a base layer formed on a side surface of the substrate, wherein a photo-etching compensation pattern layer is formed on the base layer and comprises a plurality of compensation patterns disposed in an array arrangement, and the compensation patterns are disposed between the base layer and the substrate; and
a wiring layer formed on a side surface of the base layer away from the substrate, wherein a pattern formed from the wiring layer comprises a plurality of grooves or a plurality of minor holes, the grooves or the minor holes form a plurality of interval areas for spacing patterns, and the compensation patterns respectively correspond to the interval areas for spacing patterns along a thickness direction of the substrate.

13. The array substrate of claim 12, wherein widths of the compensation patterns are greater than or equal to widths of the grooves along a horizontally extending direction of the compensation patterns.

14. The array substrate of claim 12, wherein the compensation patterns are formed by using an individual photo-etching mask.

15. The array substrate of claim 12, wherein the photo-etching compensation pattern layer is an amorphous silicon semiconductor layer, an insulating layer, or a metal conductive layer.

16. The array substrate of claim 12, wherein the base layer comprises a plurality of structures of the array substrate comprising a shading layer, a gate layer, an insulating layer, and an active layer.

17. The array substrate of claim 12, wherein a layer to be manufactured is disposed on the side surface of the base layer away from the substrate, and the light-sensitive layer is configured to form a photo-etching pattern during a process of forming a pattern of the layer to be manufactured.
